(19) United States
(12) Patent Application Publication
(10) Pub. No.: US 2026/0343912 A1
(43) Pub. Date: Oct. 29, 2026

(54) CAPACITOR USING HIGH-K AMORPHOUS FLUORINATED CARBON THIN FILM, MANUFACTURING METHOD THEREOF AND SEMICONDUCTOR USING THE SAME

(71) Applicant: THE INDUSTRY & ACADEMIC COOPERATION IN CHUNGNAM NATIONAL UNIVERSITY (IAC), Daejeon (KR)

(72) Inventor: Eui-Tae KIM, Daejeon (KR)

(73) Assignee: THE INDUSTRY & ACADEMIC COOPERATION IN CHUNGNAM NATIONAL UNIVERSITY (IAC), Daejeon (KR)

(21) Appl. No.: 19/110,818

(22) PCT Filed: Jun. 13, 2023
(86) PCT No.: PCT/KR2023/008121

§ 371 Date: Mar. 12, 2025

(30) Foreign Application Priority Data
Sep. 15, 2022 (KR) 10-2022-0116333

(51) Int. Cl. H10D 1/68; H10B 12/00; H10D 1/00; H10D 84/80

(52) U.S. Cl. CPC H10D 1/68; H10B 12/315; H10B 12/482; H10B 12/488; H10D 1/041; H10D 1/692; H10D 1/716; H10D 84/813

(57) ABSTRACT

A capacitor includes: a bottom electrode; a top electrode; and a capacitor dielectric film disposed between the bottom electrode and the top electrode, comprising an amorphous fluorinated carbon thin film having a dielectric constant of at least 10. The amorphous fluorinated carbon thin film further comprises hydrogen trapped in dangling bonds of the amorphous carbon thin film. The amorphous fluorinated carbon thin film has a leakage current of 10 A/cm² or less at an equivalent oxide thickness of 0.1 nm and an applied voltage of 1V.

### CROSS-REFERENCE TO PRIOR APPLICATIONS

This Application is a National Stage Patent Application of PCT International Application No. PCT/KR2023/008121 (filed on Jun. 13, 2023), which claims priority to Korean Patent Application No. 10-2022-0116333 (filed on Sep. 15, 2022), which are all hereby incorporated by reference in their entirety.

### BACKGROUND

The present invention relates to a capacitor comprising an amorphous fluorinated carbon thin film having a high dielectric constant, low leakage current, and high dielectric strength as a dielectric film, a manufacturing method thereof, and a semiconductor device using the same.

The gate length of metal oxide semiconductor field-effect transistors (MOSFETs), which are crucial in the fabrication of very large-scale integrated circuits (VLSI), has rapidly decreased from 10 μm to 10 nm over the past few decades. As the thickness of the SiO₂ gate dielectric decreases, gate tunneling current increases exponentially, causing excessive standby power in integrated circuits, thus the utility of SiO₂ thin films as a conventional insulating film has reached its limit. Therefore, with the integration of semiconductor devices such as memory devices and logic devices, development of high-k dielectrics with a high dielectric constant, low leakage current, and high dielectric strength is required to replace SiO₂ (k=3.9).

Materials having higher dielectric constants than SiO₂ are commonly referred to as high-k dielectrics. Ta₂O₄ and Al₂O₃ were initially applied as high-k materials, and since the adoption of sub-100 nm nodes in the late 2000s, alternative metal oxides such as ZrO₂ (k=25), HfO₂ (k=35), Al₂O₃ (k=10), and TiO₂ (k=41) have been extensively investigated to reduce gate leakage and power consumption. Currently, research is being conducted in various directions, such as identifying alternative materials to replace Hf sources (Al, Zr, Ta, STO, BST, etc.) or developing deposition methods that incorporate additional materials with Hf sources.

These high-k dielectrics can mostly be applied to devices in the form of oxide thin films. However, the high-k layer of metal oxides contains numerous bulk traps such as oxygen vacancies, increasing CV hysteresis and causing threshold voltage instability. Furthermore, as the device node size shrinks to the 10 nm scale, an equivalent oxide thickness (EOT) of 1 nm or less is required, and under these conditions, electron tunneling can occur in Hf- or Zr-based oxides. Moreover, Hf-based oxides are prone to crystallization due to their low crystallization temperature, exhibit thermal instability when in contact with Si, and have a high defect density. Zr-based oxides have high film crystallinity, resulting in a rough surface and a high density of grain boundaries, leading to very high leakage current. Ti-based oxide films inherently have a low bandgap energy of 3.5 eV, causing problems due to high leakage current and low dielectric strength. Therefore, nm nodes, the for the development of devices with sub-10 application of a novel high-k dielectric material with low leakage current and high dielectric strength is required.

Organic electronic devices have drawn significant attention due to their potential as large-area, low-cost, and flexible devices. Most organic materials are either amorphous or poorly crystalline, exhibiting smooth surfaces. Among organic materials, carbon is the most versatile material, and carbon thin films are receiving considerable attention in technical and industrial applications due to their excellent electrical and mechanical properties. The electrical properties of materials are directly related to their structure, and the key to the diversity of carbon-based materials also lies in their chemical bonding. σ-bonds between sp³ state carbon atoms generally exhibit insulating properties. Diamond is a strong insulator (conductivity <10⁻¹⁵ Ω⁻¹ cm⁻¹) and is extremely hard because its carbon atoms are only connected by sp³ bonds. On the other hand, in the presence of π-bonds associated with groups of carbon atoms in the sp² state, electrons are delocalized and can be used as charge carriers. Graphite has sp² bonds and, unlike diamond, exhibits high conductivity (10⁴ Ω⁻¹ cm⁻¹).

It is well known that the bonding of carbon materials can be controlled by adjusting the deposition temperature during the manufacture of carbon thin films. Notably, chemical vapor deposition (CVD) is a widely used technique for fabrication of carbon thin films, capable of producing high-quality graphene and carbon nanotubes at high temperatures of approximately ~1000 °C. When the deposition temperature is lowered to about 700 °C during CVD, nanographite structures are formed, and amorphous carbon is formed at room temperature. Research on carbon-based materials has focused particularly on nanostructures with highly aligned structures, such as graphene and carbon nanotubes, which have high potential as transparent conductors or next-generation semiconductors due to their high conductivity characteristics and transparency. As a result, despite nanographite and amorphous carbon also exhibiting several interesting characteristics, attempts to develop materials with new properties utilizing these and to apply them have received relatively little attention.

As nanographite and amorphous carbon contain a considerable proportion of so-called “dangling bonds”, which are fixed free radicals, they form amorphous hydrogenated carbon films by reacting with hydrogen and/or HC radicals under appropriate conditions. However, attempts to develop and apply materials with new properties by utilizing dangling bonds in nanographite or amorphous carbon have been limited. In the prior art, amorphous hydrocarbon films were limited to use as etching masks due to the ease of forming thin films of uniform thickness, or as low-k dielectric materials such as interlayer materials for semiconductor metal wiring to prevent thin film defects and increase interlayer adhesion.

Similar to amorphous hydrogenated carbon films, amorphous fluorinated carbon (a-C:Fs) films can be formed in the presence of fluorine and/or FC (fluorocarbon) radicals. Korean Patent No. 10-0283007 reports that when manufacturing amorphous fluorinated carbon by increasing fluorine concentration in amorphous carbon, the permittivity can be further lowered compared to amorphous hydrogenated carbon. Accordingly, amorphous fluorinated carbon films have been mainly reported to be used as insulating films (Korean Patents No. 10-0427508, No. 10-0283007, Japanese Patent No. 3666106) utilizing their low permittivity characteristics, and there have been no reports on amorphous fluorinated carbon films having high-k properties.

### SUMMARY

The present invention aims to solve the problems of the prior art by providing a capacitor comprising a novel high-k amorphous fluorinated carbon thin film having a high dielectric constant, low leakage current and high dielectric strength, which makes it useful for manufacturing highly integrated devices, and to a manufacturing method thereof and semiconductor device comprising the capacitor.

To achieve the aforementioned objectives, the present invention relates to a capacitor comprising: a bottom electrode; a top electrode; and a capacitor dielectric film disposed between the bottom electrode and the top electrode, comprising an amorphous fluorinated carbon thin film having a dielectric constant of at least 10.

Throughout the specification, when any part “comprises” any component, unless specifically stated otherwise, this means that other components are not excluded but may be further included. Also, when any part such as a layer, film, region, or plate is “on” or “above” another part, this includes not only cases where it is “directly on” the other part but also cases where other parts exist in between. Conversely, when any part is “directly on” another part, it means there are no other parts in between. Furthermore, when any part is formed “entirely” on another part, this includes not only cases where it is formed on the entire surface of the other part but also cases where it is not formed on some edges.

In this specification, “amorphous” is a term used in contrast to “crystalline,” indicating the absence of long-range order in atomic positions. That is, the “amorphous” thin film of the present invention may be composed entirely of an amorphous phase, but may include nano-crystalline regions having short-range order. In the amorphous fluorinated carbon thin film of the present invention, the bonding between carbon atoms may include both sp² and sp³ bonds, but the ratio thereof does not limit the thin film of the present invention.

Furthermore, in this specification, the term “amorphous fluorinated carbon thin film” refers to an amorphous carbon thin film containing fluorine trapped in dangling bonds, and does not exclude the presence of other elements trapped by dangling bonds. For example, the amorphous fluorinated carbon thin film of the present invention may further comprise hydrogen trapped by dangling bonds. In the thin film, fluorine may be bonded in the form of —CF, —CF₂, or —CF₃.

According to the prior art, amorphous carbon thin films were known to be low-k thin films with very low dielectric constants, and when fluorine was incorporated into amorphous carbon thin films, the permittivity was known to decrease further. The semiconductor structure of the present invention is characterized in that it comprises an amorphous fluorinated carbon ultrathin film, unlike conventional amorphous fluorinated carbon films, exhibiting high-k dielectric characteristics as a capacitor dielectric film. In the present invention, the amorphous fluorinated carbon ultrathin film is characterized by having a dielectric constant of 10 or more, preferably 0 or more, which surpasses the dielectric constants of conventional Hf-based, Zr-based, or Ti-based oxide films, and more preferably 60 or more.

In the capacitor of the present invention, the amorphous fluorinated carbon thin film has very low surface roughness due to its amorphous structure, with an rms surface roughness of 5 nm or less, preferably 3 nm or less, and more preferably 2 nm or less. Due to the low surface roughness, an ultrathin film with a thickness of 10 nm or less can be formed without pinholes, and low leakage current and high dielectric strength characteristics can be achieved.

While conventional high-k materials are difficult to apply to devices with nodes of 10 nm or less due to high leakage current, low dielectric strength, and high CV hysteresis characteristics, the high-k amorphous fluorinated carbon thin films not only have dielectric constant values but also exhibit excellent high electrical characteristics. Based on an equivalent oxide thickness of 0.1 nm, the amorphous fluorinated carbon ultrathin film of the present invention has a leakage current of 10 A/cm² or less at an applied voltage of 1 V, a dielectric strength of 10 MV/cm or more, and a CV hysteresis of 5 mV or less, making it useful even in devices with nodes of 10 nm or less.

In the capacitor of the present invention, the capacitor dielectric film may be composed solely of an amorphous fluorinated carbon thin film having a dielectric constant of 10 or more, or the capacitor dielectric film may be composed of a stack of multiple dielectric layers, wherein one of the multiple dielectric layers may be composed of an amorphous fluorinated carbon thin film having a dielectric constant of 10 or more. The remaining dielectric layers among the multiple dielectric layers may be composed of one or more materials selected from silicon oxide, silicon oxynitride, hafnium oxide, hafnium silicon oxide, hafnium oxynitride, hafnium silicon oxynitride, lanthanum oxide, lanthanum aluminum oxide, zirconium oxide, zirconium silicon oxide, zirconium oxynitride, zirconium silicon oxynitride, tantalum oxide, titanium oxide, barium strontium titanium oxide, barium titanium oxide, strontium titanium oxide, yttrium oxide, aluminum oxide, and lead scandium tantalum oxide.

Another aspect of the present invention relates to a method for manufacturing a capacitor comprising an amorphous fluorinated carbon thin film having a dielectric constant of 10 or more as a capacitor dielectric film. In the capacitor of the present invention, the amorphous fluorinated carbon thin film is formed by: (A) placing a substrate on which a bottom electrode is formed in a plasma reactor; (B) introducing a first gas containing fluorocarbon gas and a second gas containing an inert gas into the reactor; and (C) generating plasma in the reactor; wherein at least one of the temperature of the reactor, pressure, flow rate of the first gas, flow rate of the second gas, and plasma intensity is controlled to grow an amorphous thin film having a dielectric constant of 10 or more.

In the present invention, a plasma reactor refers to one that induces the reaction of reaction gases by generating plasma in the reactor, examples of which include plasma-enhanced chemical vapor (PE-CVD), inductively coupled plasma chemical vapor deposition deposition (ICP-CVD), or electron cyclotron resonance chemical vapor deposition (ECR-CVD) reactors. Plasma generates a large amount of highly reactive radicals from reaction gases, enabling thin film formation even at low temperatures. Although ICP-CVD is provided as an example in the following embodiments, the invention is not limited thereto.

In the present invention, any substrate commonly used in thin film manufacturing may be used. For example, it includes not only conventional substrates for manufacturing semiconductor devices such as silicon, glass, metal, and metal oxide substrates, but also substrates with active layers formed thereon according to specific implementations of semiconductor devices, substrates with graphene and two-dimensional nanomaterials such as MoS₂, MoSe₂, WS₂, WSe₂ layers formed thereon, and the like. Additionally, a capacitor dielectric film other than the high-k amorphous fluorinated carbon may be formed on the bottom electrode. According to the present invention, since no separate catalyst layer is required for the growth of amorphous fluorinated carbon thin films, the amorphous fluorinated carbon thin film can be directly deposited on the substrate where the thin film will be stacked without going through a separate transfer process. However, it does not exclude forming the thin film by growing an amorphous fluorinated carbon thin film on a substrate and then transferring it to another substrate. Furthermore, since film growth is possible at temperatures below 400 °C, even in cases including polymer substrates such as polyimide, film growth is possible without damaging the substrate.

The characteristics of the amorphous fluorinated carbon thin film constituting the capacitor dielectric film are determined by the temperature of the reactor, pressure, flow rate of the first gas, flow rate of the second gas, and plasma intensity, and an amorphous fluorinated carbon thin film having a dielectric constant of 10 or more can be grown by controlling each variable. Each variable is described in detail below. Naturally, the optimized absolute values of each variable may vary depending on the specific equipment used, and by referring to the following description of variables, it will be possible to manufacture a thin film with an appropriate thickness, dielectric constant, and surface roughness for the intended use.

The first gas comprises a fluorocarbon gas. Any fluorocarbon gas that can be used to form a fluorinated carbon thin film via plasma can be used, and carbon-based compounds commonly used for graphene manufacture by chemical vapor deposition at high temperatures, for example, compounds selected from the group consisting of methane, ethane, propane, ethylene, acetylene and propylene, wherein hydrogen is substituted with fluorine, can be used. The substitution of hydrogen with fluorine includes not only complete substitution of all hydrogen atoms in the compound but also partial substitution of hydrogen with fluorine. For example, compounds wherein the hydrogen in methane is substituted with fluorine include not only CF₄ used in the examples but also CHF₃, CH₂F₂ and CH₃F. If the fluorocarbon contains hydrogen atoms, hydrogen may be trapped along with fluorine by dangling bonds in the thin film. Also, this does not exclude fluorinated carbons other than the compounds mentioned above.

The second gas comprises an inert gas and acts as a carrier gas that controls the pressure in the reactor and the concentration of fluorocarbon. The second gas may further comprise hydrogen. Even when hydrogen is present in the second gas, hydrogen can be trapped along with fluorine by dangling bonds. Therefore, when hydrogen is present in the second gas, the ratio of fluorine and hydrogen trapped by dangling bonds in the thin film can be controlled by adjusting the volume ratio of the fluorocarbon gas in the first gas and the hydrogen gas in the second gas. The volume ratio of fluorocarbon gas in the first gas to the hydrogen gas in the second gas can be set to 100:0 to 1:50. It is natural that as the volume ratio of hydrogen gas increases, the ratio of hydrogen to fluorine trapped by dangling bonds increases, and if the volume ratio of hydrogen gas to fluorocarbon gas exceeds 1:50, the trapping ratio of fluorine may become too low.

The volume ratio of the first gas to the second gas may be, for example, 1:1 to 1:100. If the ratio of the second gas is too high compared to the first gas, the thin film growth may be too slow or may become difficult, and if the ratio of the second gas is too low, the film surface may become rough, degrading the surface characteristics.

When plasma is applied in the presence of fluorocarbon gas, a fluorinated carbon thin film is formed on the substrate. It is already well known that during the deposition of carbon thin films using carbon gas, high-quality graphene films are formed at high temperatures above 900 °C, and as the temperature decreases, dangling bonds increase and the crystallinity of the graphene film decreases. In the manufacture of the thin film of the present invention, the characteristics of the resulting thin film also changed depending on the temperature of step (C). At high temperatures, graphene is formed, and as the temperature decreases, nano-graphite containing nano-graphene crystals in the amorphous thin film is formed, and when the thin film manufacturing temperature is further lowered, the high-k amorphous fluorinated carbon thin film of the present invention is formed. Although the high-k characteristics of thin films manufactured at room temperature to 400 °C are described in the following embodiments, since they may vary depending on other reaction conditions such as the equipment used, fluorocarbon gas concentration, pressure in the reactor, and plasma intensity, restricting them to specific values is meaningless, and considering various conditions, it is preferable to control the reaction temperature within the range of 20 to 700 °C.

In step (C), the pressure in the reactor is preferably between 0.1 and 10 Torr to ensure smooth plasma discharge. If the pressure is too high, it is difficult to maintain the plasma, resulting in reduced thin film deposition efficiency, and if the pressure is too low, the process efficiency decreases.

The plasma intensity also affects the properties of the resulting thin film. Preferably, the intensity of the plasma is controlled in the range of 100 W to 1,000 W. As the intensity of the plasma increases, the growth rate of the thin film increases, the surface roughness decreases, and the dielectric constant tends to increase (data not shown), therefore intensities above 1,000 W are not excluded. Furthermore, when the plasma intensity is low, the thickness or surface roughness of the thin film can be controlled by increasing the deposition time, and the dielectric constant may also change accordingly. Therefore, plasma intensities below 100 W are not excluded either.

The optimal temperature, pressure, flow rate of the first gas, flow rate of the second gas, and plasma intensity of the reactor are factors that influence each other, so even if one variable exhibits an optimal value at a specific value when other variables are fixed, it is natural that its absolute value may change as other variables are adjusted.

The present invention confirms the characteristics of amorphous fluorinated carbon thin films whose high-dielectric properties have not been known until now, and aims to apply them in the form of an ultrathin film to semiconductor structures, and it will be easy for those skilled in the art to design them by varying the conditions to achieve optimal characteristics, including desired thickness, dielectric constant, and surface roughness, depending on the design of other components constituting the semiconductor structure.

Yet another aspect of the present invention relates to a semiconductor device comprising a capacitor that includes the high-k amorphous fluorinated carbon film as a capacitor insulating film. The semiconductor device of the present invention may include memory devices or logic devices. For example,
i) The semiconductor device may comprise:
a substrate;
source/drain regions arranged facing each other on the substrate;
a gate electrode disposed on the substrate for applying an electric field;
a gate dielectric film interposed between the gate electrode and the substrate;
a contact structure electrically connected to the source/drain regions; and
a capacitor connected to the contact structure,
according to the present invention.

In another embodiment, the device may comprise:
a substrate with a defined active region;
a word line extending in a first direction across the active region;
a gate dielectric film interposed between the word line and the active region;
a bit line extending in a second direction intersecting the first direction above the word line;
a contact structure connected to the active region; and
a capacitor connected to the contact structure,
according to the present invention.

It should be understood, however, that these are illustrative embodiments of specific configurations of the semiconductor device of the present invention and are not limited thereto.

As described above, the semiconductor structure of the present invention comprises a high-k amorphous fluorinated carbon thin film as a capacitor dielectric film, which has a dielectric value significantly higher than not only SiO₂ but also conventional Hf- or Zr-based oxides, while exhibiting very low leakage current and high dielectric strength characteristics, making it more useful for implementing semiconductor devices with sub-10 nm node.

Furthermore, since the high-k amorphous fluorinated carbon thin film does not require a catalyst layer during manufacture, it can be deposited directly onto the desired substrate without requiring a transfer process, resulting in excellent interfacial characteristics that can improve performance of capacitors and semiconductor devices. Additionally, since high-k film formation is possible even at low temperatures below 400 °C, it can be applied to flexible devices that are vulnerable to heat.

### BRIEF DESCRIPTION OF THE DRAWINGS

FIG. 1 shows Raman spectra of thin films grown at different deposition temperatures.

FIG. 2 shows an AFM image of an amorphous fluorinated carbon thin film.

FIG. 3 shows IR spectra of thin films according to deposition temperatures.

FIG. 4 shows XPS spectra of thin films according to deposition temperatures.

FIG. 5 shows C-V curves of amorphous fluorinated carbon thin films according to deposition temperatures.

FIG. 6 is an HR-TEM image showing the interface between the Si substrate and the amorphous fluorinated carbon thin film.

FIG. 7 is graphs showing the thickness and dielectric constant of thin films as a function of deposition temperature.

FIG. 8 shows a J-V curves of amorphous fluorinated carbon thin films according to deposition temperatures.

FIG. 9 is a cross-sectional view illustrating the structure of a capacitor of the present invention utilizing a high-k amorphous fluorinated carbon film.

FIG. 10 is a cross-sectional view illustrating a semiconductor device according to an embodiment of the present invention utilizing a high-k amorphous fluorinated carbon film.

FIG. 11 is a cross-sectional view illustrating a semiconductor device according to an embodiment of the present invention utilizing a high-k amorphous fluorinated carbon thin film.

### DETAILED DESCRIPTION

The present invention will now be described in more detail with reference to the accompanying drawings and exemplary embodiments. However, these drawings and examples are merely illustrative to facilitate explanation of the technical content and scope of the present invention, and the technical scope of the present invention is neither limited nor altered thereby. It would be apparent to those skilled in the art that various modifications and variations are possible within the scope of the technical concept of the present invention based on these examples.

### EXAMPLE

### Example 1: Preparation of Amorphous Fluorinated Carbon Thin Films

Under the following conditions, fluorinated carbon thin films were deposited on an n-type crystalline Si (100) substrate using CF₄ gas and a hydrogen/argon mixture by inductively-coupled plasma chemical vapor deposition (ICP CVD). Specifically, 10 sccm of CF₄ gas and 100 sccm of hydrogen/argon gas mixture (10% hydrogen) were individually introduced into the reactor. The Si substrate was cleaned by standard cleaning methods, first with a 10% HF solution for 30 s and then washed with DI water. During deposition, the pressure was fixed at 1 Torr, plasma power at 400 W, and deposition time at 30 min, while the deposition temperature was controlled in the range from room temperature to 400 °C to examine the effects of deposition temperature.

### Example 2: Characterization of Carbon Thin Films as a Function of Deposition Temperature

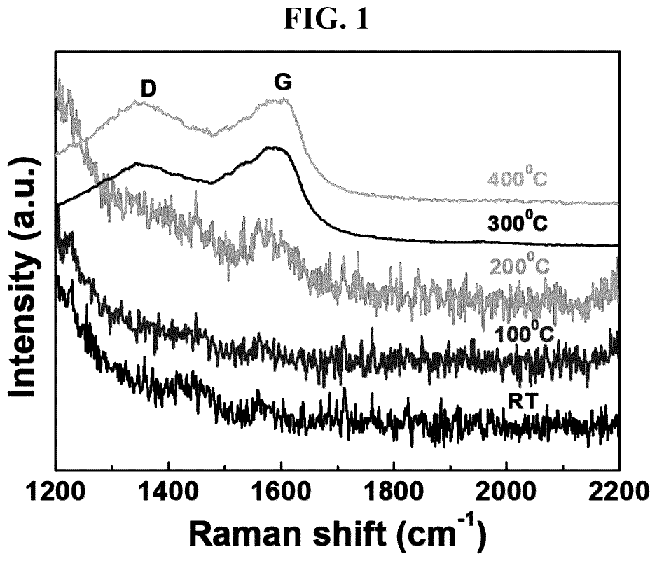

Raman spectra were observed for thin films formed at different deposition temperatures, and the results are shown in FIG. 1. The Raman spectra of samples deposited at low temperatures of room temperature or 100 °C showed only the G band at 1575 cm⁻¹, indicating the formation of completely disordered amorphous fluorinated carbon (a-C:F) thin films consisting mostly of disordered six-membered rings or rings of different orders and almost completely sp²-bonded. In the sample deposited at 200 °C, the intensity of the G peak increased significantly, and as the deposition temperature was further increased to 300 °C and 400 °C, the G peak shifted from 1575 cm⁻¹ to 1599 cm⁻¹, and a new D peak was observed, indicating graphitization of the amorphous carbon thin film. The appearance of the D peak indicates that the amorphous carbon is ordered but has a disordered structure of graphite. The appearance of the D peak and the shift of the G peak suggest a decrease in the sp³/sp² ratio, and it was expected that the dielectric properties of the amorphous fluorinated carbon thin film could be controlled through changes in the sp³/sp² ratio.

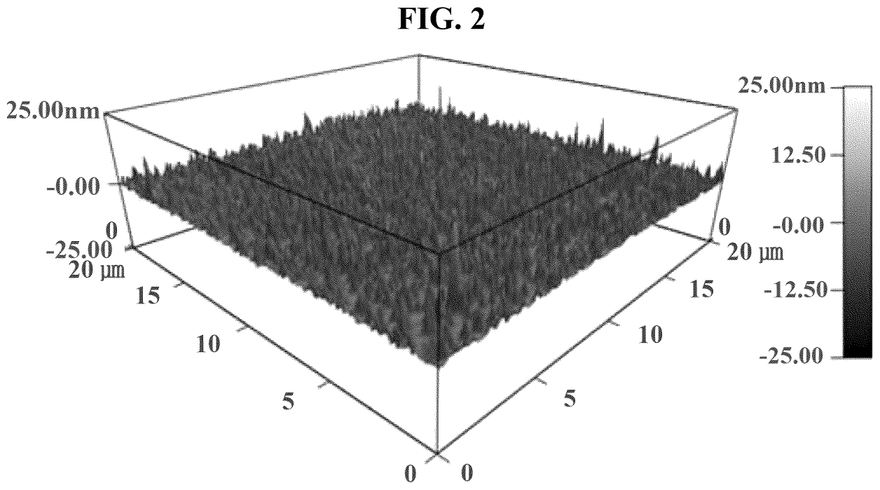

FIG. 2 is an AFM (Asylum Research, MFP-3D) image of an amorphous fluorinated carbon thin film grown directly on a Si substrate, confirming a uniform, pinhole-free and smooth thin film was grown. The thin film had a surface roughness (root-mean-square roughness) value of 1.4 nm.

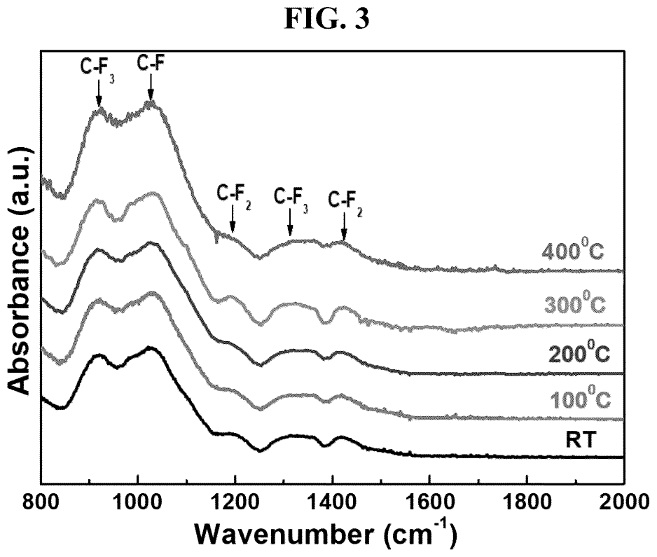

The chemical structure of the resulting amorphous fluorinated carbon thin films was confirmed by FTIR (Nicolet 6700 Fourier transform infrared spectrometer). FIG. 3 shows the IR spectra of the thin films according to deposition temperature, with all the films showing similar spectra regardless of the growth temperature. The strong peak at 1030 cm⁻¹ is attributed to the asymmetric stretching of F atoms along the direction parallel to the C—F bond. The absorption bands at 923 cm⁻¹ and 1314 cm⁻¹ are attributed to C—F₃ stretching, and the absorption bands at 1192 cm⁻¹ and 1314 cm⁻¹ are attributed to symmetric and asymmetric stretching of C—F₂. Therefore, the FTIR spectra confirmed the presence of C—F, C—F₂, and C—F₃ bonds in all the films produced at each temperature, and thus the films produced are amorphous fluorinated carbon thin films with fluorine trapped in the dangling bonds.

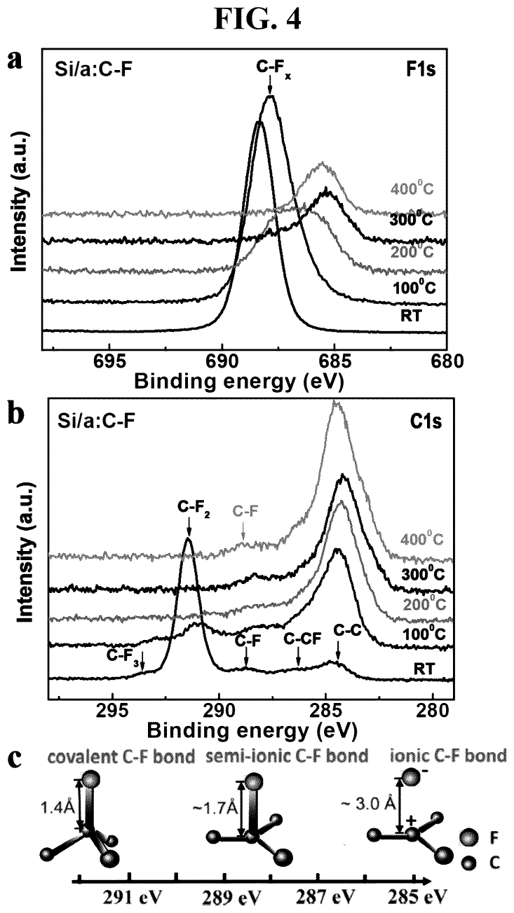

The chemical bonding in the thin films was further confirmed by XPS (K-Alpha X-ray photoelectron spectrometer) measurements. As shown in FIG. 4a, the peak position for C—Fₓ bonds in the Fis spectrum shifted to lower energy from 688.3 eV to 685.4 eV as the F/C ratio decreased with increasing growth temperature of the thin film. In particular, the XPS spectra showing Cis binding energy shown in FIG. 4b exhibited significant variations depending on the thin film growth temperature. In the XPS spectrum of the thin film deposited at room temperature, the peaks for C—F, C—F₂, and C—F₃ bonds were dominant, but when the deposition temperature increased to 100 °C, the C—C peak increased dramatically, while the C—F peak gradually increased whereas the C—F₂ and C—F₃ peaks decreased significantly. As the deposition temperature further increased to 200, 300, and 400 °C, peaks due to C-C and C—F bonds became predominant. As shown in FIG. 4c, C—F bonds have the longest bond length of 3.0 Å compared to C—F₂ bonds (1.7 Å) or C—F₃ bonds (1.4 Å). Therefore, the predominance of C—F bonds in the amorphous fluorinated carbon thin film is expected to enhance both the dipole moment and the dielectric characteristics of the thin film.

### Example 3: Evaluation of Electrical Properties of Amorphous Fluorinated Carbon Thin Films

An MIS device utilizing the amorphous fluorinated carbon thin film of the present invention as a dielectric layer was fabricated, and the electrical properties of the amorphous fluorinated carbon thin film were evaluated. Specifically, an MIS device was fabricated by forming circular Ti (5 nm)/Au (200 nm) electrodes by DC sputtering on the amorphous fluorinated carbon thin film grown on a Si substrate following the method described in Example 1.

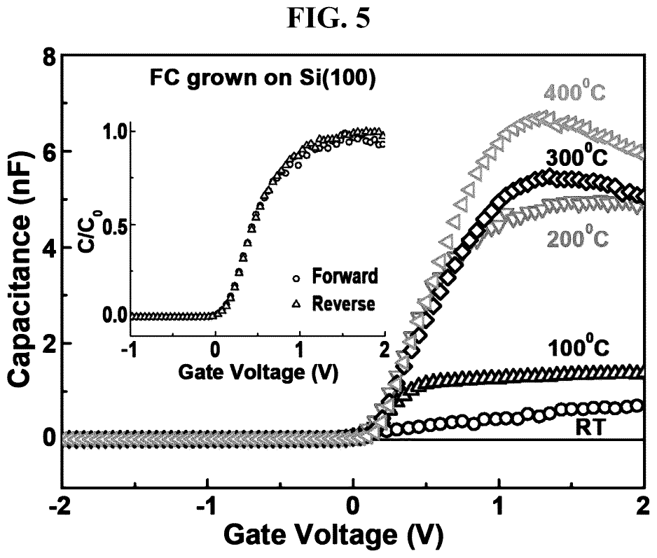

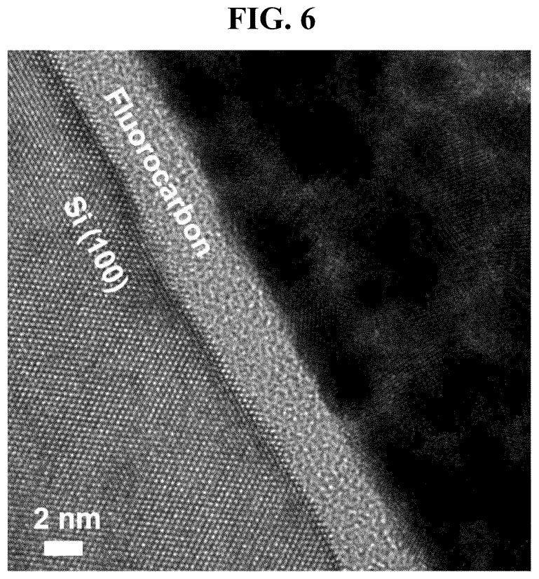

FIG. 5 shows the C-V curves of the amorphous fluorinated carbon thin film measured from the fabricated MIS device, showing a significant increase in capacitance as the film growth temperature increases. In the inset graph, o represents values measured in the forward direction from −2 V to 2 V, and Δ represents values measured in the reverse direction from +2 V to −2 V. The hysteresis in the C-V loops for all samples showed values close to zero (<5 mV). Extremely small hysteresis indicates that the trapped charge density at the interface between the amorphous fluorinated carbon thin film and the Si substrate is very low. The excellent interfacial characteristics can be explained by (i) the formation of fluorinated dangling bonds at the S1 interface during the growth of the amorphous fluorinated carbon thin film by ICP-CVD and (ii) the absence of an interfacial oxide layer between Si and the amorphous fluorinated carbon layer, as confirmed by the HR-TEM image in FIG. 6.

The dielectric constant of an amorphous fluorinated carbon thin film can be calculated from the C-V curves using the following equation.

k=dCₘₐₓ/ε₀A
where k is the dielectric constant, d is the thickness of the film, Cₘₐₓ is the accumulation capacitance, ε₀ is the permittivity in vacuum, and A is the area of the MIS device.

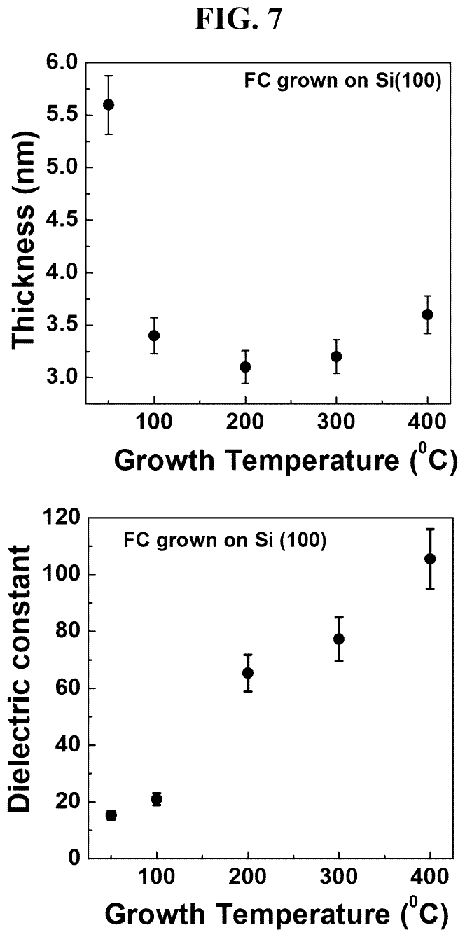

The upper graph in FIG. 7 shows the thickness of amorphous fluorinated carbon thin films grown at each deposition temperature measured using an ellipsometer M-2000, indicating that the film grown at room temperature had a thickness of 5.5 nm while films grown at 100-400 °C. had a thickness ranging from 3 to 3.5 nm. The dielectric constant calculated from the film thickness was plotted against deposition temperature and is shown in the lower part of FIG. 7. The dielectric constant increased slightly for the thin film deposited at 100 °C compared to the thin film deposited at room temperature, but showed a sharp increase at deposition temperatures of 200 °C and above. These results are consistent with the Raman and XPS spectra shown in FIGS. 1 and 3. The dielectric constant of the amorphous fluorinated carbon thin film grown at 400 °C. was 105, which demonstrates a significantly higher permittivity than not only the previously reported dielectric constants of 20-30 for Hf- and Zr-based oxides but also the dielectric constant of 90 for the amorphous carbon thin film reported by the present inventors in Korean Patent No. 10-2314727 and others.

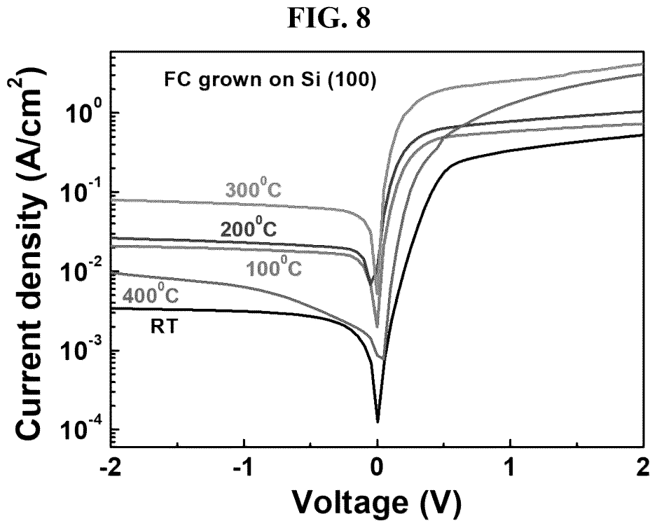

An important requirement for high-k dielectrics is low leakage current density and high dielectric strength. To verify the practical utility of the amorphous fluorinated carbon thin film as a gate dielectric material, J-V measurements were conducted and the results are shown in FIG. 8. The amorphous fluorinated carbon thin film grown at 400 °C, which exhibited the highest permittivity with a dielectric constant of 105, demonstrated an excellent MIS leakage current density of approximately 5 A/cm² at an applied voltage of 1V for an equivalent oxide thickness (EOT) of 0.1 nm. Furthermore, no breakdown phenomenon was observed up to 3V, the voltage applied for J-V measurements, confirming that the dielectric strength has a high value of at least 10 MV/cm. These leakage current and dielectric strength values are at least comparable to, if not superior to, those of recently reported high-k oxides.

### Example 4: Implementation Examples of Capacitors and Semiconductor Devices

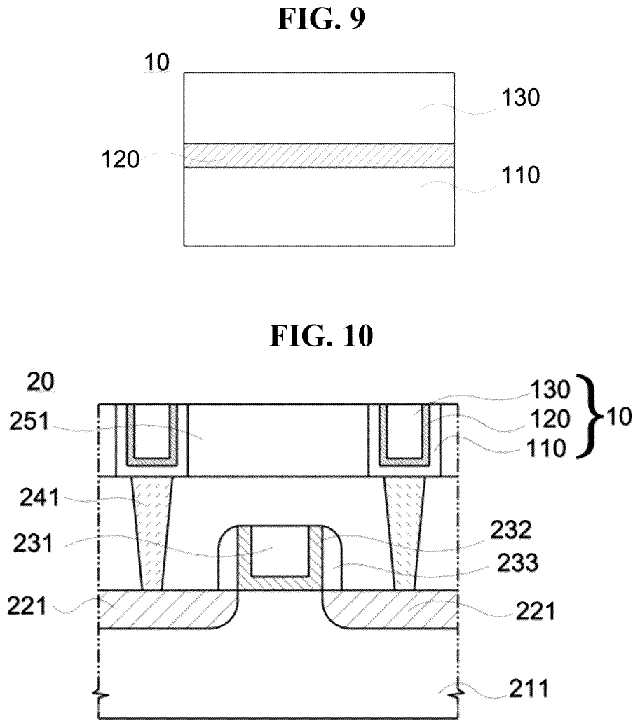

In this embodiment, a capacitor of the present invention and semiconductor devices comprising the capacitor are described with reference to FIGS. 9 to 11. However, those skilled in the art to which the present invention pertains will understand that the semiconductor device of the present invention may be implemented in other specific forms without altering its technical concept or essential characteristics. Therefore, the following embodiments should be understood in all aspects as exemplary and not limiting. Hereinafter, when it is determined that detailed descriptions of known technologies related to the invention may unnecessarily obscure the essence of the invention, such descriptions will be omitted.

FIG. 9 is a cross-sectional view of a capacitor (10) comprising a bottom electrode (110), a capacitor dielectric film (120), and a top electrode (130).

As semiconductor devices have become highly integrated, even with the use of trench-type capacitor structures, MIS (Metal-Insulator-Semiconductor) capacitors are unable to achieve the desired capacitance due to the formation of a low-dielectric film between the dielectric film and the polysilicon layer. Accordingly, MIM capacitors have been introduced to replace the MIS capacitors, and the capacitor dielectric film can be formed using the aforementioned amorphous fluorinated carbon thin film as a high-dielectric film, thereby achieving characteristics of low leakage current density and high dielectric strength.

In the capacitor of the present invention, the capacitor dielectric film may consist solely of an amorphous fluorinated carbon thin film having a dielectric constant of 10 or more, or the capacitor dielectric film may be configured as a stack of multiple dielectric layers wherein one of the multiple dielectric layers is composed of an amorphous fluorinated carbon thin film having a dielectric constant of 10 or more. The remaining dielectric layers among the multiple dielectric layers may be composed of one or more materials selected from silicon oxide, silicon oxynitride, hafnium oxide, hafnium silicon oxide, hafnium oxynitride, hafnium silicon oxynitride, lanthanum oxide, lanthanum aluminum oxide, zirconium oxide, zirconium silicon oxide, zirconium oxynitride, zirconium silicon oxynitride, tantalum oxide, titanium oxide, barium strontium titanium oxide, barium titanium oxide, strontium titanium oxide, yttrium oxide, aluminum oxide, and lead scandium tantalum oxide.

The bottom electrode (110) may be made of a single metal film or may be formed as a multi-layer film. For example, the bottom electrode (110) may comprise at least one material selected from Al, Cu, Ti, TiN, Ta, and TaN. The structure of the bottom electrode (110) may be formed as one selected from a stack structure, a cylindrical structure, and a concave structure, but is not limited thereto.

The top electrode (130) may also be formed of a single metal film or may be formed as a multi-layer film. For example, the top electrode (130) may be formed as one selected from a conductive metal film, a metal nitride film, a metal oxide film, a metal oxynitride film, and a doped polysilicon film. Alternatively, the top electrode and the bottom electrode may be formed of the same material.

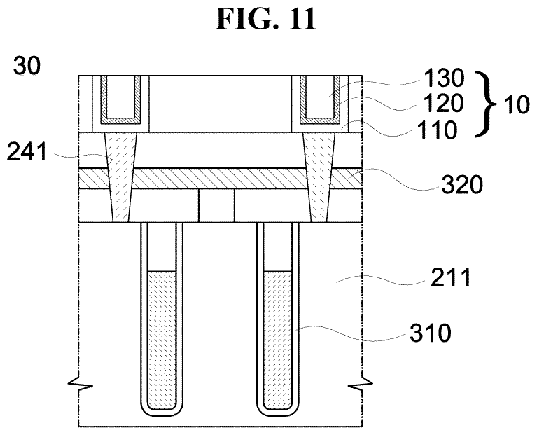

FIGS. 10 and 11 are exemplary cross-sectional views of semiconductor devices comprising the capacitor.

First, FIG. 10 illustrates a semiconductor device (20) comprising a substrate (211), source/drain regions (221), a gate electrode (231), a gate dielectric film (232), contact structures (241) and capacitors (10).

The substrate (211) may be any one of a variety of substrates used in conventional semiconductor device processes, such as glass, plastic, or a silicon substrate. In some embodiments, the substrate (211) may be composed of semiconductors such as silicon (Si) and germanium (Ge), or compound semiconductors such as SiGe, SiC, GaAs, InAs, InP. In other embodiments, the substrate may have a silicon-on-insulator (SOI) structure. In still other embodiments, the substrate may have other active layers formed on its surface.

The substrate may further comprise active regions defined by a device isolation film). The device isolation film may be a single insulating film, but may also include external and internal insulating films. The external and internal insulating films may be formed of the same material or different materials. For example, the external insulating film may be formed of an oxide film and the internal insulating film may be formed of a nitride film, but is not limited thereto.

The substrate comprises source/drain regions (221) disposed opposite each other, defining a channel region between them. The source/drain regions may be formed within the substrate or may be formed by protruding from the substrate.

The gate electrode (231) is disposed on the substrate to apply an electric field to the channel region. The gate electrode may comprise a single gate film or may be formed from multiple films. In some embodiments, the gate electrode (231) may comprise at least one material selected from the group consisting of doped semiconductors, metals, conductive metal nitrides, or metal silicides.

A gate dielectric film is interposed between the gate electrode (231) and the substrate (211). The gate dielectric film may be formed using the high-k fluorinated carbon thin film described above, or may be formed of other low-k material films or high-k material films. For example, it may be composed of a material selected from silicon oxide film, silicon oxynitride film, hafnium oxide film, zirconium oxide film, tantalum oxide film, and titanium oxide film, but is not limited thereto. In FIG. 10, while the gate dielectric film is shown as being formed on both the bottom and sides of the gate electrode, it may be formed only on the bottom of the gate electrode.

Spacers (233) may additionally be formed on the sides of the gate electrode and the gate dielectric film. The spacers may be formed of at least one of silicon oxide, silicon nitride, and silicon oxynitride. While FIG. 10 shows the spacers as being formed in a single layer, it is apparent that they are not limited thereto and may be formed in multiple layers.

The contact structure (241) is arranged to be electrically connected to the source/drain regions. In some embodiments, the contact structure may be referred to as source/drain contacts. The contact structure may be formed of one or more selected from conductive metal films, metal nitride films, metal oxide films, metal oxynitride films, and doped semiconductor materials.

The capacitor (10) is electrically connected to the source/drain regions by being connected to a contact structure. For this reason, in some embodiments, the contact structure may be referred to as a capacitor contact or a source/drain contact.

The capacitor comprises a bottom electrode (110), a top electrode (130), and a capacitor dielectric film (120) interposed between the bottom electrode and the top electrode. As described above, in the present invention, the capacitor dielectric film is formed to include an amorphous fluorinated carbon thin film with a dielectric constant of 10 or more, having characteristics of low leakage current density and high dielectric strength. The bottom electrode, top electrode, and capacitor dielectric film may be substantially identical to those described in the explanation of FIG. 9.

In the semiconductor device of the present invention, an insulating film (251) may prevent the bottom electrode from making electrical contact with other active regions. The insulating film may be formed as a single layer of insulating film, but may also include multiple insulating films. The multiple insulating films may be formed of different materials. For example, one of the multiple insulating films may be formed of an oxide film, and another of the multiple insulating films may be formed of a nitride film, but it is not limited thereto.

FIG. 11 is a cross-sectional view illustrating a semiconductor device (30) according to another embodiment. The semiconductor device of this embodiment comprises a substrate (211), word lines (310), a bit line (320), contact structures (241), and capacitors (10).

The substrate (211) can be substantially identical to that described in the explanation of FIG. 9, and the active region of the substrate can likewise be defined by a device isolation films (not shown) as described above. For example, the device isolation film may be formed by creating a trench in the upper region of the substrate and filling the trench with an insulating film. Furthermore, the device isolation film may consist of a single film or multiple layers of insulating films.

The semiconductor device (30) of the present invention comprises a word line (310) extending in a first direction across the active region. In FIG. 9, the word line is shown in the form of a vertical channel formed inside the substrate, but is not limited thereto. The word line may be a single line or may be formed as a multiple mutually parallel lines. When formed as multiple lines, they may be arranged at equal intervals, and the width or spacing may be appropriately determined according to the design of the semiconductor device. The word line is formed in a manner that fills the lower portion of a trench formed in the substrate, and its upper surface may be lower than the upper surface of the active region. The word line may be formed of at least one material selected from, for example, Ti, TiN, Ta, TaN, W, WN, TiSiN, and WSiN, but is not limited thereto. In cases where the upper surface of the word line is lower than the upper surface of the active region, as shown in FIG. 11, it may be aligned with the active region by an insulating film or a mask used in further processing. The insulating film may be formed of silicon oxide film, silicon nitride film, silicon oxynitride film, or a combination thereof. Between the word line and the active region, a gate dielectric film is interposed.

A plurality of bit lines (320) may be arranged on the word line, extending mutually parallel in a second direction that intersects with the word line. The bit lines may also be arranged at regular intervals, and the width or spacing may be appropriately determined according to the design of the semiconductor device.

The capacitor (10) is electrically connected to the source/drain regions by the contact structure. For this reason, in some embodiments, the contact structure may be referred to as a capacitor contact or a source/drain contact. The contact structure may be formed of one or more materials selected from conductive metal films, metal nitride films, metal oxide films, metal oxynitride films, and doped semiconductor materials.

The capacitor comprises a bottom electrode (110), a top electrode (130), and a capacitor dielectric film (120) interposed between the bottom electrode and the top electrode. As described above, in the present invention, the capacitor dielectric film is formed to comprise an amorphous fluorinated carbon thin film with a dielectric constant of 10 or more, having characteristics of low leakage current density and high dielectric strength. The bottom electrode, top electrode, and capacitor dielectric film may be substantially identical to those described in the explanation of FIG. 9.

[Description of the Symbols]

| | |
|---|---|
| 10: Capacitor | |
| 110: Bottom electrode | 120: Capacitor dielectric film |
| 130: Top electrode | |
| 20, 30: Semiconductor device | |
| 211: Substrate | 221: Source/drain regions |
| 231: Gate electrode | 232: Gate dielectric film |
| 233: Spacer | |
| 241: Contact structure | 251: Insulating film |
| 310: Word line | 320: Bit line |

1. A capacitor comprising:
a bottom electrode;
a top electrode; and
a capacitor dielectric film disposed between the bottom electrode and the top electrode, comprising an amorphous fluorinated carbon thin film having a dielectric constant of at least 10.

2. The capacitor of claim 1, wherein the amorphous fluorinated carbon thin film further comprises hydrogen trapped in dangling bonds of the amorphous carbon thin film.

3. The capacitor of claim 1, wherein the amorphous fluorinated carbon thin film has a leakage current of 10 A/cm² or less at an equivalent oxide thickness of 0.1 nm and an applied voltage of 1V.

4. The capacitor of claim 3, wherein the amorphous fluorinated carbon thin film has a dielectric strength of 10 MV/cm or more at an equivalent oxide thickness of 0.1 nm.

5. A capacitor according to claim 1, wherein the capacitor dielectric film comprises a stack of multiple dielectric layers, and one of the multiple dielectric layers is composed of an amorphous fluorinated carbon thin film having a dielectric constant of 10 or more.

6. The capacitor according to claim 5, wherein the remaining dielectric layers among the multiple dielectric layers comprise one or more materials selected from silicon oxide, silicon oxynitride, hafnium oxide, hafnium silicon oxide, hafnium oxynitride, hafnium silicon oxynitride, lanthanum oxide, lanthanum aluminum oxide, zirconium oxide, zirconium silicon oxide, zirconium oxynitride, zirconium silicon oxynitride, tantalum oxide, titanium oxide, barium strontium titanium oxide, barium titanium oxide, strontium titanium oxide, yttrium oxide, aluminum oxide, and lead scandium tantalum oxide.

7. The capacitor according to claim 1, wherein the bottom electrode is characterized by being formed as one selected from a stack structure, a cylindrical structure, and a concave structure.

8. The capacitor according to claim 1, wherein the top electrode is characterized by being formed as one selected from a conductive metal film, a metal nitride film, a metal oxide film, a metal oxynitride film, and a doped polysilicon film.

9. A method of manufacturing a capacitor according to claim 1, wherein the amorphous fluorinated carbon thin film having a dielectric constant of 10 or more constituting the capacitor dielectric film is characterized by being formed by:
(A) placing a substrate on which a bottom electrode is formed in a plasma reactor;
(B) introducing a first gas containing fluorocarbon gas and a second gas containing an inert gas into the reactor; and
(C) generating plasma in the reactor;
wherein at least one of the temperature of the reactor, pressure, flow rate of the first gas, flow rate of the second gas, and plasma intensity is controlled to grow an amorphous thin film having a dielectric constant of 10 or more.

10. A semiconductor device characterized by comprising a capacitor according to claim 1.

11. The semiconductor device according to claim 10, characterized by comprising:
a substrate;
source/drain regions arranged facing each other on the substrate;
a gate electrode disposed on the substrate for applying an electric field;
a gate dielectric film interposed between the gate electrode and the substrate;
a contact structure electrically connected to the source/drain regions; and
a capacitor connected to the contact structure.

12. The semiconductor device according to claim 10, characterized by comprising:
a substrate with a defined active region;
a word line extending in a first direction across the active region;
a gate dielectric film interposed between the word line and the active region;
a bit line extending in a second direction intersecting the first direction above the word line.
a contact structure connected to the active region; and
a capacitor connected to the contact structure.
